(19) United States
(12) Patent Application Publication
(10) Pub. No.: US 2005/0189629 A1
(43) Pub. Date: Sep. 1, 2005

(54) Method of manufacturing a semiconductor device

(76) Inventors: Fujio Ito, Hanno (JP); Hiromichi Suzuki, Nishishinkoiwa (JP); Tokuji Toida, Hamura (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/066,174

(22) Filed: Feb. 28, 2005

(30) Foreign Application Priority Data
Feb. 27, 2004 (JP) 2004-053675

(51) Int. Cl. H01L 21/48; H01L 23/495

(52) U.S. Cl. 257/676; 438/123

(57) ABSTRACT

A method for manufacturing a semiconductor device includes the steps of providing a semiconductor device of a surface mounted type in which the main surface of a chip mounting portion connected to a semiconductor chip is formed so as to be smaller than the main surface of the semiconductor chip, accommodating the semiconductor device into a non-moistureproof, e.g., flammable, packing, and shipping the packed semiconductor device. The non-moistureproof packing may have a moisture permeability of T T≧1 g/m²/24 hr. The method may also include providing a second semiconductor device of a surface-mounted type in which the main surface of a chip mounting portion connected to a semiconductor chip is formed so as to be larger than the main surface of the semiconductor chip, moistureproof-packing the second semiconductor device, and shipping and packed second semiconductor device.

### CROSS-REFERENCE TO RELATED APPLICATION

The present application claims priority from Japanese patent application No. 2004-053675, filed on Feb. 27, 2004, the content of which is hereby incorporated by reference into this application.

### BACKGROUND OF THE INVENTION

The present invention relates to a method of manufacturing a semiconductor device and to a package used therein. Particularly, the present invention is concerned with a technique that is applicable to effect reduction of the environmental load in the shipment of semiconductor devices.

A conventional surface-mounting type semiconductor package typically is accommodated in a magazine which serves as an auxiliary member for conveyance and is received within a moisture-proof laminate bag. The laminate bag is hermetically sealed with a humidity indicator accommodated therein. Further, the surface-mounted type semiconductor package is sealed completely, and the occurrence of package interface peeling or cracking at the time of packaging is prevented.

(See, for example, Patent Literature 1).

[Patent Literature 1]

Japanese Unexamined Patent Publication

No. Hei 8(1996)-34483 (FIG. 6)

### SUMMARY OF THE INVENTION

For attaining a reduction in the size and weight of electronic devices and for improving the rationalization of their packaging, surface-mounted type semiconductor packages (hereinafter referred to as “surface-mounted packages”) are experiencing widespread use as a substitute for the pin insertion type semiconductor package. For example, the QFP (Quad Flat Package), TSOP (Thin Small Outline Package), SOJ (Small Outline J-leaded Package), and QFN (Quad Flat Non-leaded Package) are known surface-mounted type packages. Some of them are described in the foregoing Patent Literature 1 (Japanese Unexamined Patent Publication No. Hei 8(1996)-34483).

For mounting a surface-mounted type package, such as any of those referred to above, a solder reflow mounting method (e.g., infrared reflow or air reflow) is typically employed. At the time of mounting the package, the whole of the package is exposed to a high temperature (a peak temperature of 260° to 265° C.), often causing the package to crack.

A cause of this cracking of the package results from the fact that moisture absorbed into the package during storage of the package after assembly or during shipping thereof expands rapidly at the reflow temperature and generates a large stress. When this stress exceeds the strength of the package (resin), a crack in the package results. This tendency is more outstanding in the case of using a lead-free solder, such as tin-silver (Sn—Ag), whose melting temperature is relatively high.

As a measure for preventing the occurrence of such cracking of the package, semiconductor manufacturers use moistureproof packing at the time of shipping surface-mounting type packages to electronic device manufacturers (customers). An example of moisture-proof packing is described in the above-referenced Patent Literature 1.

For moistureproof packing, a laminate bag (moisture permeability: 0-10⁻¹ g/m²/24 hr) is used, and silica gel serving as a desiccant is placed to the bag. However, the moistureproof packing, after being unsealed, becomes a waste product which is unnecessary to the customer, so that the semiconductor manufacturer side is required to dispose of the waste product. Thus, how to handle the moistureproof packing after it is unsealed is a problem which remains to be solved on the semiconductor manufacturer side.

Recently, reduction of the environmental load has become a serious international problem, and enterprises are being required to reduce the environmental load. As a means for reduction of the environmental load, not only restriction of the use of such harmful substances as lead, but also the reduction of packing waste, has recently been proposed. That is, it is now considered necessary to simplify or re-utilize packing materials.

It is an object of the present invention to provide a method of manufacturing a semiconductor device which can reduce the environmental load, as well as to provide a packing used therein.

The above and other objects and novel features of the present invention will become apparent from the following description and the accompanying drawings.

Typical modes of the present invention as disclosed herein will be outlined below.

In one aspect of the present invention, there is provided a method of manufacturing a semiconductor device, comprising the steps of providing a first semiconductor device of the surface-mounted type, in which the main surface of a chip mounting portion connected to a semiconductor chip is formed so as to be smaller than the main surface of the semiconductor chip, and a second semiconductor device of the surface-mounted type, in which the main surface of a chip mounting portion connected to a semiconductor chip is formed so as to be larger than the main surface of the semiconductor chip;
non-moistureproof-packing the first semiconductor device and shipping the thus-packed first semiconductor device; and moistureproof-packing the second semiconductor device and shipping the thus-packed second semiconductor device.

In another aspect of the present invention, there is provided a method of manufacturing a semiconductor device, comprising the steps of providing a semiconductor device of the surface-mounted type, in which the main surface of a chip mounting portion connected to a semiconductor chip is formed so as to be smaller than the main surface of the semiconductor chip; accommodating the semiconductor device into a flammable packing; and shipping the thus-packed semiconductor device.

In a further aspect of the present invention, there is provided a method of manufacturing a semiconductor device, comprising the steps of providing a semiconductor device of the surface-mounted type, in which the main surface of a chip mounting portion connected to a semiconductor chip is formed so as to be smaller than the main surface of the semiconductor chip; accommodating the semiconductor device into a packing having a moisture permeability of T≧1 g/m²/24 hr; and shipping the thus-packed semiconductor device.

In a still further aspect of the present invention, there is provided a packing which is formed of a flammable material and is capable of accommodating a semiconductor device of the surface-mounted type, in which the main surface of a chip mounting portion connected to a semiconductor chip is formed so as to be smaller than a main surface of the semiconductor chip.

In a still further aspect of the present invention, there is provided a packing which is capable of accommodating a semiconductor device of the surface-mounted type, in which the main surface of a chip mounting portion connected to a semiconductor chip is formed so as to be smaller than the main surface of the semiconductor chip, the packing having a moisture permeability T of T≧1 g/m²/24 hr.

The following is a brief description of effects obtained by typical modes of the present invention as disclosed herein.

A first semiconductor device of the surface-mounted type, having a chip mounting portion whose main surface is formed so as to be smaller than that of a semiconductor chip and a second semiconductor device of the surface-mounted type, having a chip mounting portion whose main surface is formed so as to be larger than that of the semiconductor chip, are provided; then, the first semiconductor device is non-moistureproof-packed and shipped, while the second semiconductor device is moistureproof-packed and shipped. Therefore, as compared with moistureproof-packing both of the first and second semiconductor devices, the shipping of the first semiconductor device can dispense with members that are difficult to recycle, such as a moistureproof bag made of aluminum, such a desiccant such as silica gel, and a humidity indicator. As a result, it is possible to reduce the environmental load.

### BRIEF DESCRIPTION OF THE DRAWINGS

FIG. 1 is a flow chart showing an example of using a non-moistureproof bag and a moistureproof bag selectively in a method for manufacturing a semiconductor device according to the present invention;

FIG. 2 is a sectional view showing a structural example of a semiconductor device having a small tab structure as used in the method shown in FIG. 1;

FIG. 3 is a partially cut-away perspective view showing the structure of the semiconductor device illustrated in FIG. 2;

FIG. 4 is a sectional view showing a structural example of a semiconductor device having a large tab structure used in the method shown in FIG. 1;

FIG. 5 is a sectional view showing an example of a stress-applied state during reflow in the semiconductor device having the large tab structure illustrated in FIG. 4;

FIG. 6 is a sectional view showing an example of a stress-applied state during reflow in the semiconductor device having the small tab structure illustrated in FIG. 2;

FIG. 7 is a graph showing an example of a relation between die pad size and element shear strength in the semiconductor device having the small tab structure illustrated in FIG. 2;

FIG. 8 is a partial plan view showing an example of a die pad structure in the semiconductor device having the small tab structure illustrated in FIG. 2;

FIG. 9 is a graph showing an example of a relation between die pad size and generated stress during reflow in the semiconductor device having the small tab structure illustrated in FIG. 2;

FIG. 10 is a working flow chart showing an example of how to pack the semiconductor device having the small tab structure in the semiconductor device manufacturing method illustrated in FIG. 1;

FIG. 11 is a working flow chart showing an example of how to pack the semiconductor device having the large tab structure in the semiconductor device manufacturing method illustrated in FIG. 1;

FIG. 12 is a perspective view and a partially enlarged plan view showing a packing method according to a modification of the method of manufacturing the semiconductor device having the small tab structure illustrated in FIG. 10;

FIG. 13 is a perspective view showing a packing method according to a modification of the method of manufacturing the semiconductor device having the small tab structure illustrated in FIG. 10;

FIG. 14 is a plan view showing a structural example of a principal portion of a lead frame used in assembling the semiconductor device illustrated in FIG. 2;

FIG. 15 is a plan view showing the structure of a principal portion of a modified lead frame used in assembling the semiconductor device illustrated in FIG. 2;

FIG. 16 is a plan view showing an example of a relation between a semiconductor chip and a die pad in the lead frame illustrated in FIG. 14;

FIG. 17 is a plan view showing an example of a relation between a semiconductor chip and die pads in the lead frame illustrated in FIG. 15;

FIG. 18 is a sectional view showing an example of a structural condition for non-moistureproof-packing the semiconductor device having the small tab structure illustrated in FIG. 2;

FIG. 19 is a sectional view showing an example of a structural condition for non-moistureproof-packing the semiconductor device having the small tab structure illustrated in FIG. 2; and

FIG. 20 is a sectional view showing an example of a structural condition for non-moistureproof-packing the semiconductor device having the small tab structure illustrated in FIG. 2.

### DETAILED DESCRIPTION OF THE PREFERRED EMBODIMENTS

In the following description, explanations of the same or similar portions will not be repeated in principle, except in the case where such explanations are specially needed.

Where required for convenience' sake, the subject matter of the invention will be described in a divided manner as plural sections or embodiments, but unless otherwise mentioned, they are not unrelated to each other, but are in a relation such that one is a modification, a detailed description, or a supplementary explanation, of part or the whole of the other.

In the following description of the embodiments, when reference is made to a specific number of elements (including the number, numerical value, quantity, and range), no limitation is made to the specific number referred to, but numerals above and below the number referred to will do, unless otherwise mentioned, and except in the case where it is basically evident that a limitation is made to the number referred to.

Embodiments of the present invention will be described in detail hereinunder with reference to the accompanying drawings. In all of the drawings, members having the same functions are identified by the same reference numerals, and repeated explanations thereof will be omitted.

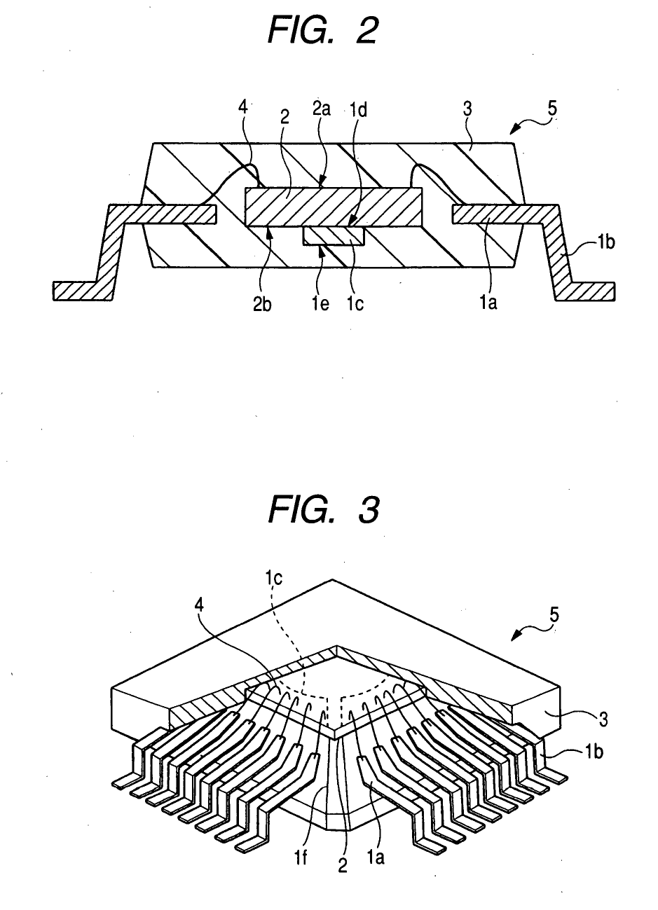

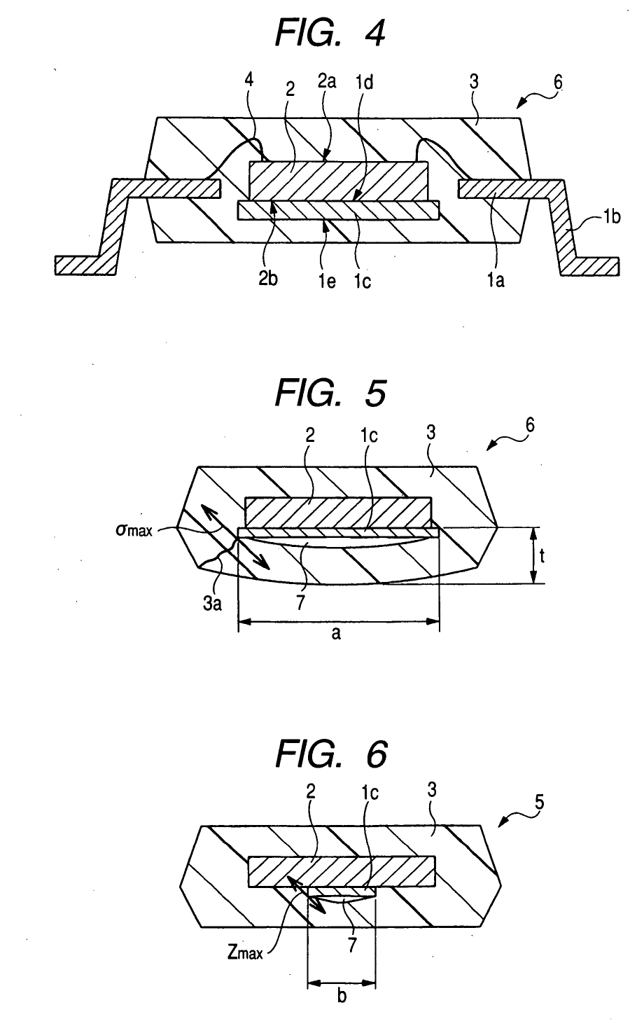

The present invention is concerned with a method of packing a semiconductor device (also designated as a surface-mounted package) of the surface-mounted type and the resin-sealed type. With a view to reducing the environmental load by a simplification of the packing, reference will be made herein to QFPs (Quad Flat Packages) 5 and 6, illustrated in FIGS. 2 and 4, respectively, as an example of a surface-mounted type semiconductor device.

The QFP 5 shown in FIGS. 2 and 3 comprises a semiconductor chip 2 having a main surface 2a with plural electrodes and a semiconductor element formed thereon; a die pad 1c, which has having a main surface 1d and a back surface 1e and is connected to a back surface 2b of the semiconductor chip 2 through a die bonding material, the die pad 1c having a chip mounting portion in which the main surface 1d is formed so as to be smaller than the main surface 2a of the semiconductor chip 2; plural inner leads 1a arranged around the semiconductor chip 2; plural wires 4, such as gold wires, for electrically connecting the electrodes of the semiconductor chip 2 to corresponding inner leads 1a; a sealing body 3 which seals the semiconductor chip 2, plural wires 4 and die pad 1c with resin; plural outer leads 1b projecting outwards from the sealing body 3, which leads 1b are connected to and integral with the inner leads 1a, the outer leads 1b being formed in a gull wing shape by bending; and suspending leads 1f connected to the die pad 1c.

Thus, the QFP 5 is a semiconductor device of the surface-mounted type, and it has a small tab structure in which the die pad 1c is formed so as to be smaller than the semiconductor chip 2 (such a structure will hereinafter be referred to also as a SDP: Small Die Pad).

In the QFP 5, a part of the sealing body 3 is disposed over the main surface 2a of the semiconductor chip 2 and under the back surface 1e of the die pad 1c, and the die pad 1c is buried completely within the sealing body 3.

On the other hand, the QFP 6 shown in FIG. 4 comprises a semiconductor chip 2 having a main surface 2a, with plural electrodes and a semiconductor element formed thereon; a die pad 1c, which has a main surface 1d and a back surface 1e and is connected to a back surface 2b of the semiconductor device 2 through a die bonding material, the main surface 1d being formed so as to be larger than the main surface 2a of the semiconductor chip 2; plural inner leads 1a arranged around the semiconductor chip 2; plural wires 4, such as gold wires, for electrically connecting the electrodes of the semiconductor chip 2 to corresponding inner leads 1a; a sealing body 3 which seals the semiconductor chip 2, the wires 4 and the die pad 1c with resin; plural outer leads 1b projecting outwards from the sealing body 3, which leads 1b are connected to and integral with the inner leads 1a, the outer leads 1b being formed in a gull wing shape by bending; and suspending leads 1f (see FIG. 3) connected to the die pad 1c.

Thus, the QFP 6 is a semiconductor device of a surface-mounted type, and it has a large tab structure in which the die pad 1c is formed so as to be larger than the semiconductor chip 2.

Also, in the QFP 6, a part of the sealing body 3 is disposed over the main surface 2a of the semiconductor chip 2 and under the back surface 1e of the die pad 1c, and the die pad 1c is completely buried within the sealing body 3.

Now, a description will be given below of a method of manufacturing the semiconductor device of this embodiment, including a method to be used for packing the semiconductor device.

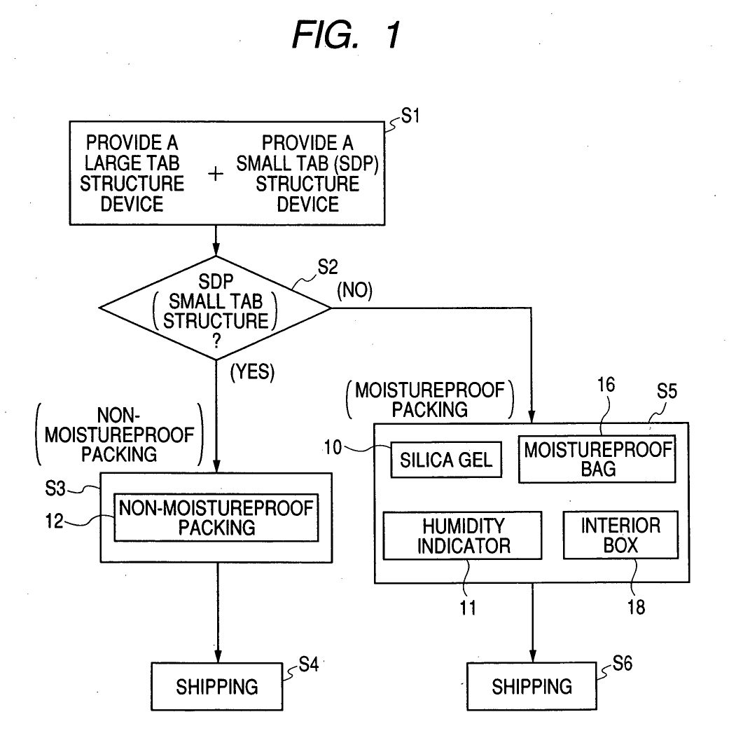

First, as shown in step S1 in FIG. 1, semiconductor devices having a large tab structure and a small tab structure are provided. More specifically, the QFP (first semiconductor device) 5 of the surface-mounted type and having a small tab structure, which is shown in FIG. 2, and the QFP (second semiconductor device) 6 of the surface-mounted type and having a large tab structure, which is shown in FIG. 4, are provided.

Thereafter, in step S2, it is determined whether the semiconductor device concerned has (YES) of a small tab structure (SDP) or not (NO), and, if the answer is affirmative (YES), the semiconductor device is non-moistureproof-packed in step S3 and is then shipped in step S4.

On the other hand, if it is determined in step S2 that the semiconductor device has a large tab structure (NO), the semiconductor device is moistureproof-packed as in step S5 and is then shipped in step S6.

More particularly, in the case of the QFP 5 having a small tab structure, the QFP 5 is placed into a non-moistureproof packing, such as a flammable bag or a non-moistureproof bag and is then shipped. On the other hand, in the case of the QFP 6 having a large tab structure, the QFP 6 is placed into an interior box 18, and then the interior box 18 is packed into a moistureproof bag 16 formed of aluminum, for example, together with silica gel 10 and a humidity indicator 11, followed by shipping.

Thus, the non-moistureproof packing and the moistureproof packing are used selectively depending on whether the semiconductor device has a small tab structure or a large tab structure.

The reason why the small tab structure is applicable to non-moistureproof packing will be set forth below.

For mounting a surface-mounted type semiconductor device, a reflow mounting method is employed. However, in a resin-sealed type plastic package, the sealing resin is apt to absorb water and the entry of water causes peeling 7 at the interface between the die pad 1c and the sealing body 3, shown as in FIG. 5. Further, water stays in the space formed by the peeled portion.

In this state, the user side performs reflow packaging with use of solder or the like. In the reflow packaging, the entire package is exposed to a high temperature (peak temperatures 260-265° C.), so that the water absorbed within the package expands suddenly and generates a large stress. If this stress exceeds the strength of the sealing body 3, a package crack 3a, as shown in FIG. 5, results.

The stress typically is concentrated at a corner portion of the die pad 1c, therefore, if this stress acting on the corner portion during reflow is assumed to be σ max, it can be expressed as a max=β×(a²/t²)×P, where P stands for the steam pressure at the peeled portion between the die pad 1c and the sealing body 3, a stands for the short-side length of the die pad 1c, t stands for the thickness of the sealing body 3 which underlies the die pad, and β is a shape constant. Thus, the stress σ max is proportional to the square of the short-side length a of the die pad 1c and is inversely proportional to the thickness t of the sealing body 3 which underlies the die pad.

The larger the short-side length a of the die pad 1c is, the larger will be the amount of water remaining in the hollow of the peeled portion 7 at the interface between the die pad 1c and the sealing body 3. Therefore, the smaller the short-side length of the die pad is, the more preferred the configuration will be, like the short-side length b of the die pad 1c as shown in FIG. 6. Further, the bonding force between silicon, which serves as the material of the semiconductor chip 2, and the sealing resin is much higher than the bonding force between the die pad 1c and the sealing resin. Thus, the larger the area of bonding between silicon and the sealing resin is, the more difficult will it be for the peeling 7 to occur.

Consequently, when the large tab structure shown in FIG. 5 and the small tab structure shown in FIG. 6 are compared with each other, a>b and, hence, τmax>Zmax. Thus, it is seen that, in the small tab structure, the peeling 7 is difficult to occur, and cracking of the package is very unlikely to occur.

In the small tab structure, as described above, even if moisture is absorbed, the area of the peeling 7 is small and the area of bonding between the semiconductor chip 2 and the sealing body 3 is large, so that the reflow resistance is high, and, hence, a semiconductor device having the small tab structure can be non-moistureproof-packed for shipping.

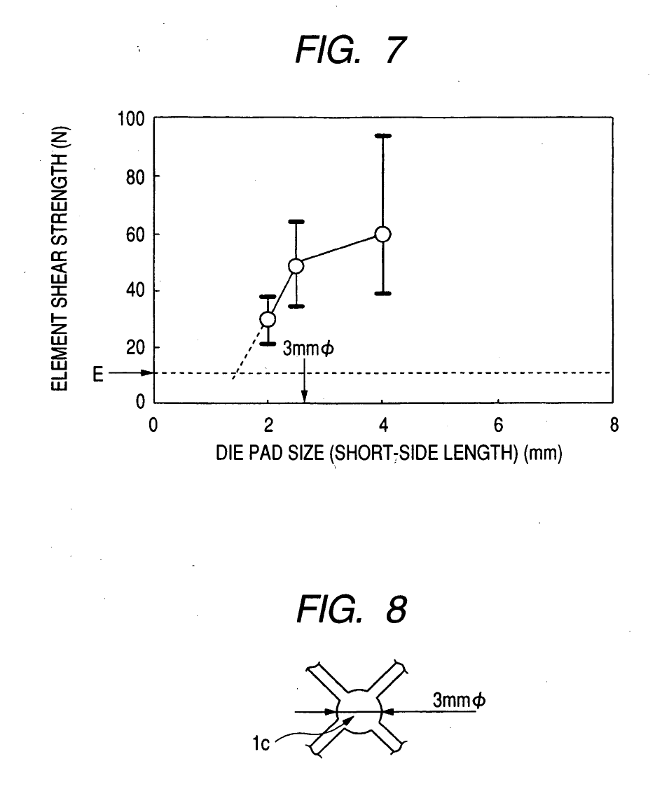

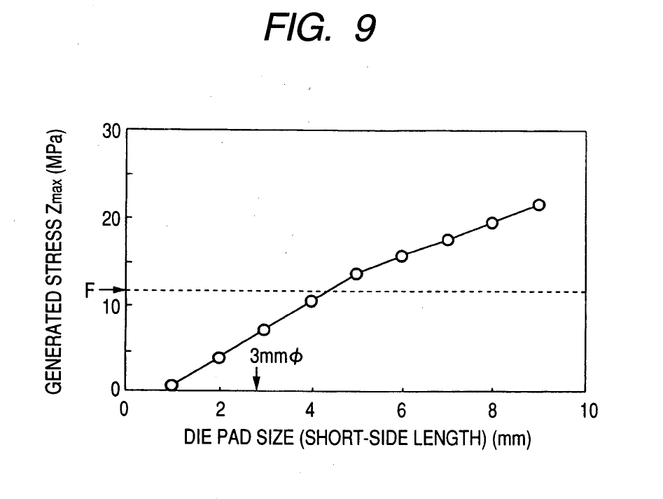

The following description provides an example of the size of the die pad 1c which is preferred in adopting the small tab structure. FIG. 7 shows an example of a relation between the short-side length of the die pad 1c of the small tab structure having a quadrangular shape and the bonding strength (shear strength) of a die bonding material (e.g., silver paste), and FIG. 9 shows an example of a relation between the short-side length of the die pad 1c of the small tab structure and the generated stress (Zmax) during reflow.

In the element shear strength shown in FIG. 7, the process work limit E is 10N, and the size of the die pad 1c is determined in a region of 10N or more in terms of element shear strength. From the standpoint of element shear strength, including margin, it is preferable that the size of the die pad 1c be 2.0 mm or more in terms of the short-side length in the quadrangular shape.

In the generated stress shown in FIG. 9, a hot breaking strength F of an ordinary sealing resin is 12 Mpa, and, therefore, the generated stress determines the size of the die pad 1c in a region of 12 MPa or less. From the standpoint of generated stress, including margin, it is preferable for the size of the die pad 1c to be 4.0 mm or less in terms of the short-side length in the quadrangular shape.

Thus, it is seen that the size of the die pad 1c should preferably be in the range of 4 to 16 mm² and that the diameter A (φ) should be 3 mm or so, taking margins above and below a median value into account. When the absorption of moisture is taken into account, the smaller the diameter A of the die pad 1c is, the more the configuration is preferred. Therefore, from the data of element shear strength shown in FIG. 7, a lower limit is encountered at about 1.5 mm in the short-side length of the quadrangular shape. Transformation of this into a circular shape results in the lower limit of the diameter A becoming about 1.6 mm.

Thus, an example of a preferred size of the die pad 1c, in the case of adopting the small tab structure for non-moisureproof packing, is as follows. In the case of a circular die pad 1c, the diameter A of the main surface 1d of the die pad 1c is 1.6 mm≦A≦4.5 mm, which corresponds to 2.0 mm²≦S≦16.0 mm² in terms of area S. Preferably, the diameter A of the main surface 1d of the die pad 1c is 1.6 mm≦A≦3.0 mm, which corresponds to 2.0 mm²≦S≦7.0 mm² in terms of area S.

However, in case of 1.6 mm≦A≦4.5 mm (2.0 mm²≦S≦16.0 mm²), the area of bonding between the semiconductor chip 2 and the die pad 1c is likely to become larger than in the case of 1.6 mm≦A≦3.0 mm (2.0 mm²≦S≦7.0 mm²). If such is the case, it is possible to enhance the bonding strength between the semiconductor chip 2 and the die pad 1c.

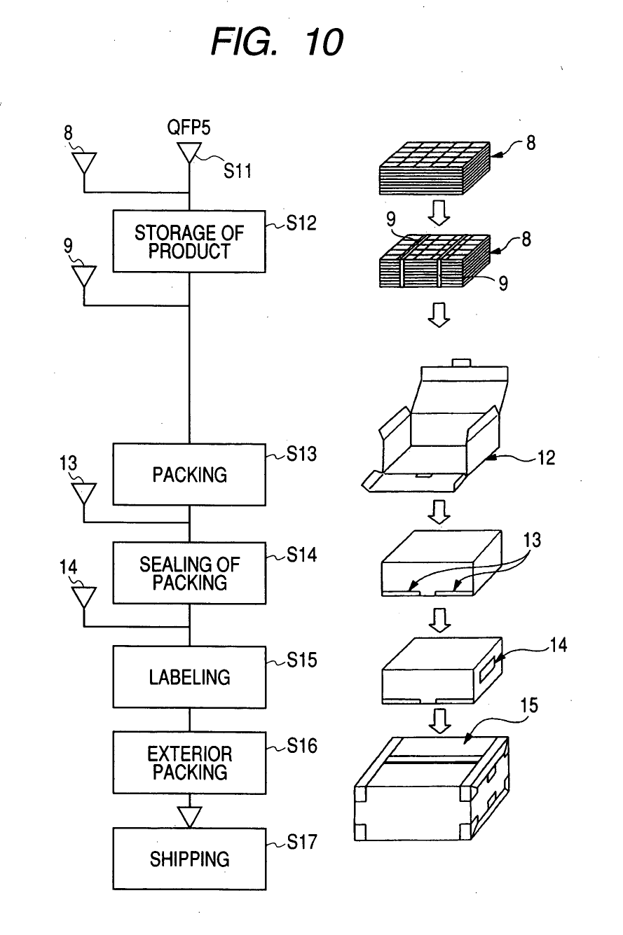

Next, with reference to FIG. 10, a description will be given of a packing and shipping method (manufacturing method) which adopts a non-moistureproof packing for a QFP 5 having a small tab structure.

First, as in step S11 shown in FIG. 10, a surface-mounted and resin-sealed type QFP 5 having a small tab structure is provided, and plural trays 8, which can receive QFPs 5 therein, are also provided. Each tray 8 may be, for example, a heat-resistant tray made of PPE (Poly-phenylene Ether) and having a heat-resisting temperature of 130-160° C., or a non-heat-resistant tray made of PS (Poly-Styrene) and having a heat-resisting temperature of 70° C. or lower. In this embodiment, for the purpose of diminishing the environmental load, a non-heat-resistant tray made of PS (Poly-Styrene) not containing chlorine, which is a harmful substance, is adopted.

Thereafter, the accommodation of the product is performed in step S12. In this step, the QFPs 5 are accommodated in the trays 8, and, after stacking each of the trays 8 accommodating the QFPs 5, the stacked trays 8 are bundled with tying bands 9.

Thereafter, storage of the product is performed in step S13. In this step, the plural trays 8 accommodating the plural QFPs 5 and which are bundled with bands 9 are packed into a flammable packing 12, which is a non-moistureproof packing. That is, the QFPs 5 having the small tab structure are non-moistureproof packed. Since the small tab structure is high in reflow resistance and can tolerate non-moistureproof packing, it is applicable to non-moistureproof packing.

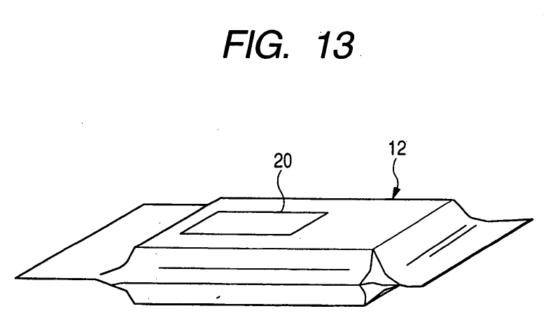

The flammable packing 12 is an example of non-moistureproof packing and is formed of a flammable material. A highly flammable material which does not produce any harmful substance during burning is preferred. An example is paper, corrugated cardboard, or vinyl. As to the shape of the packing, it may be, for example, a box-like shape, such as the flammable packing 12 shown in FIG. 10, or it may be a bag-like shape, such as the flammable packing 12 shown in FIG. 13.

The non-moistureproof packing is not limited to the flammable packing 12. For example, it may be a packing having a moisture permeability T of T≧1 g/m²/24 hr. For example, it may be a non-moistureproof packing.

As an example of a moistureproof packing that is generally used, mention may be made of a moistureproof bag 16 as a laminate bag of aluminum, which is high in moistureproofness. The moisture permeability of the moistureproof bag 16 is, for example, 0 to 10⁻¹ g/m²/24 hr.

Thus, it suffices for the non-moistureproof packing used in this embodiment to have a moisture permeability T of T≧1 g/m²/24 hr. For example, the moisture permeability T may be in the range of about 10 to 100 (g/m²/24 hr).

Flammable packing 12 may be combined with a non-moistureproof bag or the like.

After the end of packing, the packing is sealed using tapes 13 in step S14. That is, the flammable packing 12 is sealed with tapes 13.

Thereafter, labelling, i.e., the affixing of a bar code label 14, is performed in step S15. The bar code label 14 is affixed to any outside position (e.g., a side face) of the flammable packing 12.

Subsequently, exterior packing is performed in step S16. More specifically, the flammable packing 12 with the bar code label 14 affixed thereto is sealed into an exterior box 15. Then, the packing is shipped in step S17.

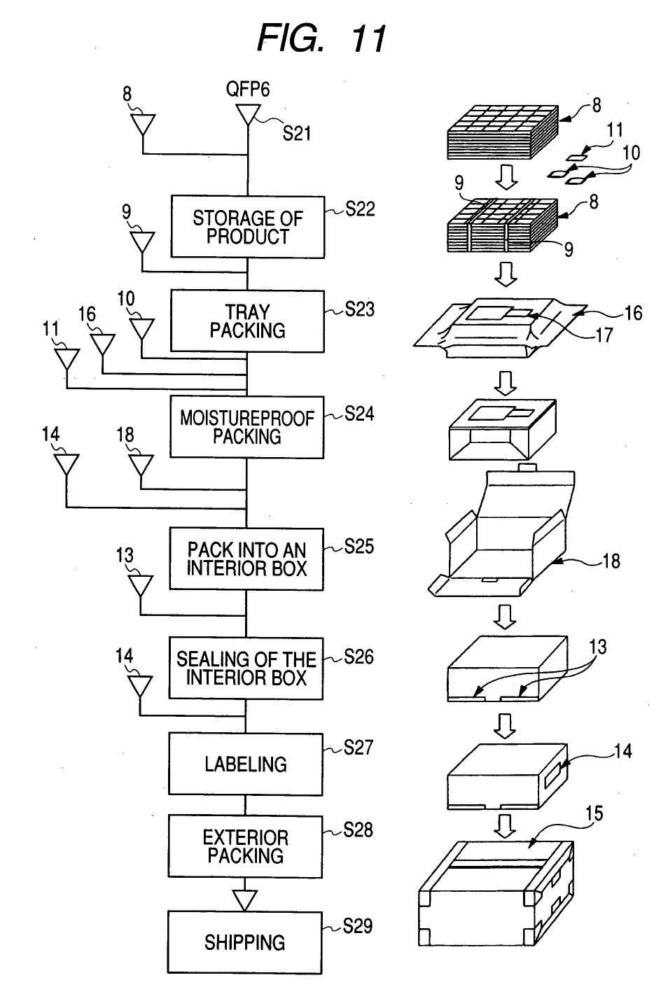

Next, with reference to FIG. 11, a description will be given of a packing and shipping method (manufacturing method) which adopts a moistureproof packing for a QFP 6 having a large tab structure.

First, in step S21 shown in FIG. 11, a surface-mounted and resin-sealed type QFP 6 having a large tab structure is provided, and a plurality of trays 8 which can receive QFPs 6 therein are also provided.

Then, the storage of the product is performed in step S22. In this step, the plural trays 8 with QFPs 6 accommodated therein are stacked and, thereafter, bundled with tying bands 9.

Thereafter, tray packing is performed in step S23. In this step, the plural trays containing plural QFPs 6, which are bundled with bands 9, are packed into a moistureproof bag 16 such as a laminate bag made of aluminum. That is, the QFPs 6 having the large tab structure are moistureproof-packed. At this time, a humidity indicator 11 and a desiccant, such as silica gel 10, are placed to the moistureproof bag together with the trays 8. For example, one humidity indicator 11 and two pieces of silica gel 10 are packed together with the trays 8.

An instruction sheet 17 and a bar code label 14 are affixed to the outside of the moistureproof bag 16.

Subsequently, moistureproof packing is performed in step S24. More specifically, the moistureproof bag 16 is heat-sealed while the interior thereof is evacuated to a vacuum state.

Then, an interior box 18 and a bar code label 14 are provided, and interior boxing is performed in step S25. In this step, the moistureproof bag 16, having been subjected to moisture packing, is packed into the interior box 18.

At the end of interior boxing, the interior box 18 is sealed with tapes 13 in step S26.

Then, in step S27, the bar code label 14 is affixed to any outside position (e.g., a side face) of the interior box 18.

Thereafter, exterior packing is performed in step S28. In this step, the interior box 18 with the bar code label affixed thereto is sealed into an exterior box 15, followed by shipping in step S29.

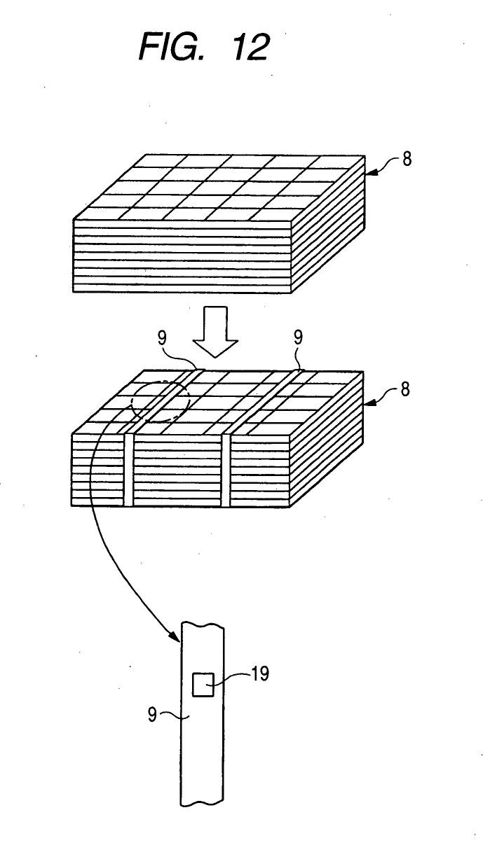

In the moistureproof packing for the QFP 5 having the small tab structure or the QFP 6 having the large tab structure, as shown in FIG. 12, a mu chip (semiconductor chip) 19 storing product information of the QFP 5 or 6 may be embedded in a band 9 for bundling the trays 8. By so doing, even after opening the packing and taking out the trays 8 on the user side, the product information of the semiconductor device stored in the trays 8 can be acquired by reading the information stored in the mu chip 19.

The place where the mu chip 19 is to be embedded is not limited to the band 9, but it may be embedded in a tray 8, or it may be affixed to the outside of the flammable packing 12 or the moistureproof bag 16.

FIG. 13 shows a modification of the flammable packing 12, which is a non-moistureproof packing used in non-moistureproof-packing the QFP 5 of the small tab structure. For example, an instructions label 20 describing how to handle the flammable packing 12 or the QFP 5 after sealing the packing 12 is disposed on the outside of the flammable packing 12.

Information indicating how to handle the non-moistureproof packing after opening and the QFP 5 is provided on the instructions label 20. The following are examples of such information: “A flammable material is used for packing”, “Does not contain any environmental load material”, “The heat-resistant characteristic of the packing material does not influence the inclusion of the outside air through pinholes or the like”, “An environment-friendly (environmentally sound) packing material is used”, “The packing is simplified”, “Baking after opening is not necessary because this simple packed product is improved in heat resistance”, “This simple packed product may be allowed to stand for 10000 hours at room temperature”.

It is optional whether the instruction label 20 is to be affixed to the outside of the non-moistureproof packing or is to be embedded in the non-moistureproof packing so as to be visible from the exterior, or whether it is to be sealed into the non-moistureproof packing.

FIGS. 14 to 17 each show an example of a relation between the shape of the die pad 1c of the small tab structure and the area of the semiconductor chip 2 in each lead frame 1. FIG. 14 shows a lead frame 1 having a single circular die pad 1c and FIG. 15 shows a lead frame having divided small die pads 1g as chip mounting portions.

The area S of the main surface 1d of the die pad 1c in case of adopting the small tab structure for non-moistureproof packing is preferably 2.0 mm²≦S≦16.0 mm², and it is more preferably 2.0 mm²≦S≦7.0 mm². Therefore, in the case of such a single circular die pad 1c as shown in FIG. 14, the area S of the main surface 1d of the die pad 1c is preferably 2.0 mm²≦S≦16.0 mm², and it is more preferably 2.0 mm²≦S≦7.0 mm². When this is applied to the divided die pads 1g shown in FIG. 15, the total area of the four divided die pads 1b is (S1+S2+S3+S4). Therefore, when such plural die pads 1g as shown in FIG. 15 are present, it is preferable to satisfy the relationship of 2.0 mm²≦S≦16.0 mm², and more preferably, 2.0 mm²≦(S1+S2+S3+S4)≦7.0 mm².

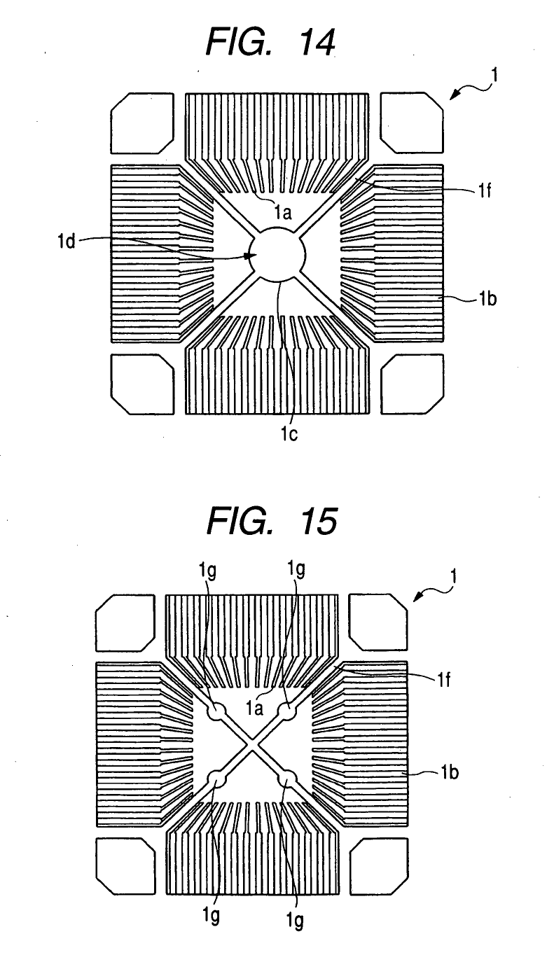

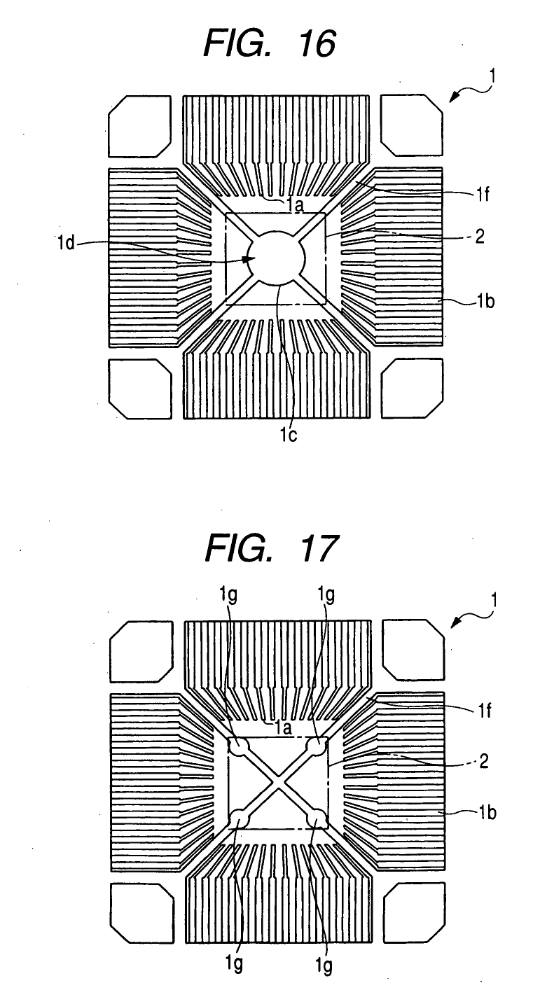

As shown in FIG. 16, it is preferable for the relation between the area (SC) of the back surface 2b of the semiconductor chip 2 and the area (S) of a single circular die pad 1c to be (SC/S)≧0.9. Further, in the case of such divided die pads 1g as shown in FIG. 17, it is preferable for the relation between the area (SC) of the back surface 2b of the semiconductor chip 2 and the total area (S1+S2+S3+S4) of the divided die pads 1g to be (SC/(S1+S2+S3+S4))≧0.9. These are conditions required of the die pad 1c in adopting the small tab structure for non-moistureproof packing.

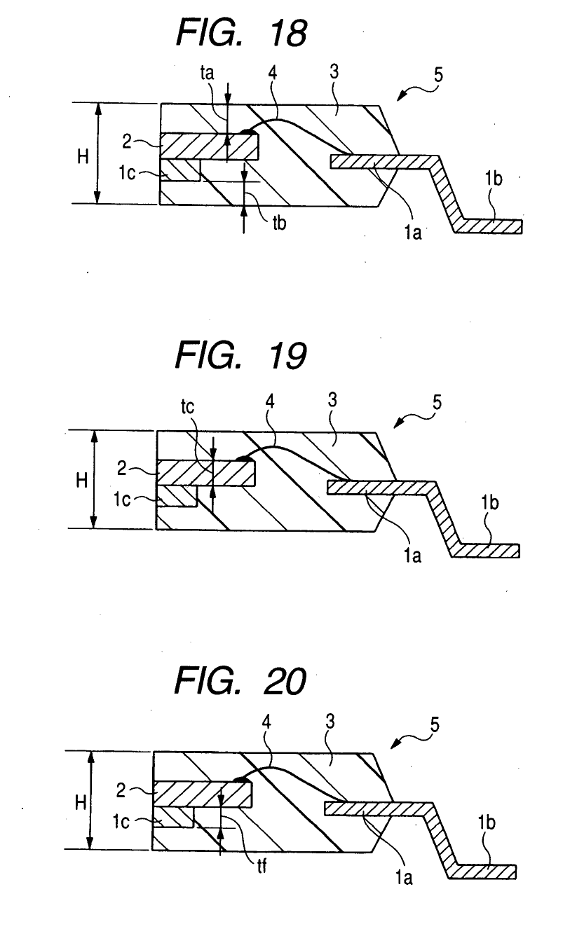

FIGS. 18 to 20 show thickness conditions in various portions of a QFP 5 in case of adopting the small tab structure for non-moistureproof packing. FIG. 18 shows conditions of an on-chip resin thickness (ta) and an under-chip resin thickness (tb) in order not to reach a resin breaking strength against stress concentration on a chip corner portion during reflow. For example, at a standard chip thickness and lead thickness relative to the package thickness (H), it is preferable for the on-chip resin thickness (ta) and the under-chip resin thickness (tb) to be set at ta≧0.7 mm and tb≧0.7 mm, respectively.

FIGS. 19 and 20 show conditions for reducing the package thickness. As shown in FIG. 19, if the package thickness (H) is assumed to be H≦2.0 mm, it is preferable for the chip thickness (tc) to be set at tc≦0.3 mm. Further, as shown in FIG. 20, if the package thickness (H) is assumed to be H≦2.0 mm, it is preferable for the die pad thickness (tf) to be set at tf□≦0.15 mm.

According to the semiconductor device manufacturing method embodying the present invention and the packing used therein, there are provided a surface-mounted type QFP 5 having a small tab structure in which the main surface 1d of the die pad 1c is formed so as to be smaller than the main surface 2a of the semiconductor chip 2, as well as a surface-mounted type QFP 6 having a large tab structure in which the die pad 1c is formed so as to be larger than the main surface 2a of the semiconductor chip 2, the QFP 5 having the small tab strucuture is non-moistureproof-packed and then shipped, while the QFP 6 having the large tab structure is moistureproof-packed and then shipped. As a result, in comparison with the conventional method wherein semiconductor devices having both small and large tab structures are both moistureproof-packed and then shipped, shipping of the QFP 5 having the small tab structure can dispense with the use of packing members that are difficult to recycle, such as the moistureproof bag 16 made of aluminum, a desiccant, such as silica gel 10, and the humidity indicator 11.

Moreover, as to the non-moistureproof packing, it becomes possible to use a non-moistureproof packing made of an environment friendly (environmentally sound) material, such as the flammable packing 12, e.g., a paper, corrugated cardboard or vinyl packing, or a packing made of a material having a moisture permeability T of T≧1 g/m²/24 hr, e.g., paper.

As a result, it is possible to diminish the environmental load.

Further, in shipping the QFP 5 having the small tab structure, it is possible to simplify the packing in both packing form and packing work because the moistureproof bag 16, silica gel 10 and humidity indicator 11 are not used, nor is moistureproof packing required.

Particularly, in case of adopting the flammable packing 12 as a non-moistureproof packing, the flammable packing 12 can be disposed of by burning, for example, in an incinerator, so that no load is imposed on the environment, and it is possible to surely attain a reduction of the environmental load in this way.

If the structure according to the present invention wherein the chip mounting portion is smaller than the chip mounted thereon, is not adopted, it is necessary, after taking out a package (semiconductor device) from the packing and before soldering, for the package to be subjected to a thermodrying treatment (generally called prebaking) on the customer side. In this case, the use of a heat-resistant tray is required in the thermodrying treatment. The heat-resistant tray is generally higher in cost than a tray which is not heat-resistant. However, by adopting the construction of the present invention, it is possible to omit the thermodrying treatment and use a non-heat-resistant tray instead of a heat-resistant tray. Consequently, it is possible to improve the mounting efficiency on the customer side, diminish the environmental load, and reduce the cost.

Although the present invention has been described above by way of various embodiments thereof, it goes without saying that the present invention is not limited to the above-described embodiments, but that various changes may be made within a scope not departing from the gist of the invention.

For example, in the above-described embodiments, both QFP 5 having a small tab structure and QFP 6 having a large tab structure are provided, and the QFP 5 is shipped in a non-moistureproof-packing, while the QFP 6 is shipped in a moistureproof packing. However, in the semiconductor device manufacturing method according to the present invention, it is not always necessary to provide both a QFP 5 having a small tab structure and a QFP 6 having a large tab structure so long as the QFP 5 having a small tab structure is provided and is shipped in a non-moistureproof packing, irrespective of whether the QFP 6 having a large tab structure is provided or not.

Although the foregoing description of the embodiments has been made with reference to QFPs 5 and 6 as an example of a surface-mounted type semiconductor device, the semiconductor device may be another type of a semiconductor device so long as it is a surface-mounted and resin-sealed type semiconductor device, such as a TSOP, SOJ, or QFN.

The present invention provides a suitable semiconductor device manufacturing technique and semiconductor device packing technique.

1. A method of manufacturing a semiconductor device, comprising the steps of:
(a) providing a first semiconductor device of a surface-mounted type in which a main surface of a chip mounting portion connected to a semiconductor chip is formed smaller than a main surface of the semiconductor chip and a second semiconductor device of a surface-mounted type in which a main surface of a chip mounting portion connected to a semiconductor chip is formed larger than the main surface of the semiconductor chip;
(b) non-moistureproof-packing the first semiconductor device and shipping the packed first semiconductor device; and
(c) moistureproof-packing the second semiconductor device and shipping the packed second semiconductor device.

2. A method according to claim 1, wherein the diameter A of the main surface of the chip mounting portion of the first semiconductor device is 1.6 mm≦A≦4.5 mm or the area S thereof is 2.0 mm²≦S≦16.0 mm².

3. A method according to claim 1, wherein the diameter A of the main surface of the chip mounting portion of the first semiconductor device is 1.6 mm≦A≦3.0 mm or the area S thereof is 2.0 mm²≦S≦7.0 mm².

4. A method of manufacturing a semiconductor device, comprising the steps of:
(a) providing a semiconductor device of a surface mounted type in which a main surface of a chip mounting portion connected to a semiconductor chip is formed smaller than a main surface of the semiconductor chip; and
(b) accommodating the semiconductor device into a flammable packing and shipping the packed semiconductor device.

5. A method according to claim 4, wherein the flammable packing is formed of paper.

6. A method according to claim 4, wherein an instructions label is disposed over or within the flammable packing.

7. A method according to claim 4, wherein the flammable packing contains plural trays with the semiconductor device accommodated therein.

8. A method according to claim 4, wherein the flammable packing contains plural trays with the semiconductor device accommodated therein, and a semiconductor chip which stores information of the semiconductor device is embedded in a band for bundling said plural trays or in the flammable packing.

9. A method according to claim 4, wherein the diameter A of the main surface of the chip mounting portion of the semiconductor device is 1.6 mm≦A≦4.5 mm or the area S thereof is 2.0 mm²≦S≦16.0 mm².

10. A method according to claim 4, wherein the diameter A of the main surface of the chip mounting portion of the semiconductor device is 1.6 mm≦A≦3.0 mm or the area S thereof is 2.0 mm²≦S≦7.0 mm².

11. A method according to claim 4, wherein the semiconductor device has a sealing body for sealing the semiconductor chip, a part of the sealing body being disposed over the main surface of the semiconductor chip and under the chip mounting portion.

12. A method of manufacturing a semiconductor device, comprising the steps of:
(a) providing a surface-mounted type semiconductor device in which a main surface of a chip mounting portion connected to a semiconductor chip is smaller than a main surface of the semiconductor chip; and
(b) accommodating the semiconductor device in a packing having a moisture permeability T of T≧1 g/m²/24 hr and shipping the packed semiconductor device.

13. A method according to claim 12, wherein the packing contains plural trays with the semiconductor device accommodated therein.

14. A method according to claim 12, wherein the packing contains plural trays with the semiconductor device accommodated therein, and a semiconductor chip which stores information of the semiconductor device is embedded in a band for bundling said plural trays or in the packing.

15. A method according to claim 12, wherein the diameter A of the main surface of the chip mounting portion of the semiconductor device is 1.6 mm≦A≦4.5 mm or the area S thereof is 2.0 mm²≦S≦16.0 mm².

16. A method according to claim 12, wherein the diameter A of the main surface of the chip mounting portion is 1.6 mm≦A≦3.0 mm or the area S thereof is 2.0 mm²≦S≦7.0 mm².

17. A method according to claim 12, wherein the semiconductor device has a sealing body for sealing the semiconductor chip, a part of the sealing body being disposed over the main surface of the semiconductor chip and under the chip mounting portion.

18. (canceled)

19. (canceled)

20. (canceled)

21. (canceled)

22. (canceled)

23. (canceled)

24. (canceled)

25. (canceled)
